(19) United States
(12) Patent Application Publication
(10) Pub. No.: US 2021/0184200 A1
(43) Pub. Date: Jun. 17, 2021

(54) HOMOGENOUS FILM COATING OF A PARTICLE

(71) Applicant: GM GLOBAL TECHNOLOGY OPERATIONS LLC, Detroit, MI (US)

(72) Inventors: Ruchira R. Dharmasena, Shelby Township, MI (US); Shuru Chen, Troy, MI (US); Fang Dai, Troy, MI (US); Mei Cai, Bloomfield Hills, MI (US)

(73) Assignee: GM GLOBAL TECHNOLOGY OPERATIONS LLC, Detroit, MI (US)

(21) Appl. No.: 16/710,793

(22) Filed: Dec. 11, 2019

(51) Int. Cl. H01M 4/04; H01M 4/136; C23C 14/34

(52) U.S. Cl. CPC H01M 4/0426; C23C 14/34; H01M 4/136; H01M 4/045

(57) ABSTRACT

A method of applying a homogenous film coating to a constituent particle of component includes setting up a target element in a sputtering chamber. The method also includes arranging a receptacle in the sputtering chamber. The method additionally includes arranging the constituent particle on the receptacle. The method also includes bombarding the target element via energetic particles to eject material from the target element and deposit the material onto the constituent particle. The method further includes agitating the receptacle during the bombarding to apply the material to the constituent particle as the homogenous film coating. The method may be used to apply a homogenous thin film coating to a sulfur-infused constituent particle for a sulfur cathode in a lithium-sulfur battery.

### GOVERNMENT LICENSE RIGHTS

This invention was made with government support under agreement No.: DE-EE0008230 awarded by the U.S. Department of Energy. The government has certain rights in the invention.

### INTRODUCTION

The present disclosure relates to a method of applying a homogenous film coating to a constituent particle of component.

A coating is a covering that is applied to the surface of an object. The purpose of applying the coating may be decorative, functional, or both. The coating itself may be an all-over coating, completely covering the object, or it may only cover parts of the object.

Functional coatings may be applied to change the surface properties of the object's material, such as adhesion, wettability, corrosion resistance, or wear resistance. In other cases, the coating adds a completely new property, and forms an essential part of the finished product.

A major consideration for most coating processes is that the coating is to be applied at a controlled thickness. Many industrial coating processes involve the application of a thin film of functional material to a substrate, such as paper, fabric, film, foil, or sheet stock. Coatings may be applied as liquids, gases, or solids in component or constituent particle form.

### SUMMARY

A method of applying a homogenous film coating to a constituent particle of component includes setting up a target element in a sputtering chamber. The method also includes arranging a receptacle in the sputtering chamber. The method additionally includes arranging the constituent particle on the receptacle. According to the method, the receptacle may be arranged in the sputtering chamber already with the constituent particle thereon, or the constituent particle may be arranged on the receptacle after the receptacle has been arranged in the chamber. The method also includes bombarding the target element via energetic particles to eject material from the target element and deposit the material onto the constituent particle. The method further includes agitating the receptacle during the bombarding to apply the material to the constituent particle as the homogenous film coating.

The material of the target element may be selected from a list of carbon allotrope and metal conductors, and semiconductors.

The homogenous film coating may have a thickness in a range of 5-50 nanometers.

Agitating the receptacle may include inducing vibration via predefined strokes at a frequency in a range of 2,000 to 20,000 strokes per minute.

The constituent particle may have a porous material matrix supporting energy dense particles, such as carbon-sulfur composite structure with a carbon matrix supporting sulfur elements.

The size of the constituent particles, i.e., dimension across a particular particle, may be in a range of 5 to 20 microns.

The method may additionally include maintaining a vacuum of 1×10⁻³ mBarr in the sputtering chamber during each of bombarding the target element and agitating the receptacle.

The method may additionally include maintaining a temperature in a range of 25 to 115 degrees Celsius in the sputtering chamber during each of bombarding the target element and agitating the tooling fixture.

Agitating the receptacle may be accomplished via DC electric motor or an ultrasonic transducer.

Bombarding the target element via energetic particles may include injecting argon gas into the sputtering chamber.

The method may be used to apply a homogenous thin film coating to a sulfur-infused constituent particle for a sulfur cathode in a lithium-sulfur battery. In the lithium-sulfur battery, the homogenous film coating is intended to enhance conductivity of the sulfur-infused constituent particle and mitigate leakage of polysulfide from the sulfur cathode.

The above features and advantages, and other features and advantages of the present disclosure, will be readily apparent from the following detailed description of the embodiment(s) and best mode(s) for carrying out the described disclosure when taken in connection with the accompanying drawings and appended claims.

### BRIEF DESCRIPTION OF THE DRAWINGS

FIG. 1 is a schematic view of electrical energy storage cell powering a load, the energy storage cell being shown as a lithium-sulfur (Li—S) battery having a lithium anode and a sulfur cathode, according to the disclosure.

FIG. 2 is a schematic perspective close-up view of the sulfur cathode, shown in FIG. 1, depicting the cathode's structure using sulfur-infused constituent particles, according to the disclosure.

FIG. 3 is a schematic cross-sectional close-up view of the cathode's constituent particle having a homogenous thin film coating.

FIG. 4 illustrates a method of applying in a sputtering chamber a homogenous film coating to constituent particle(s), such as the sulfur-infused constituent particle(s) for the Li—S battery cathode shown in FIGS. 1-3.

FIG. 5 is a schematic illustration of a system configured to generate the homogenous thin film coating on the surface of constituent particle(s) shown in FIG. 3 and for use with the method shown in FIG. 4.

### DETAILED DESCRIPTION

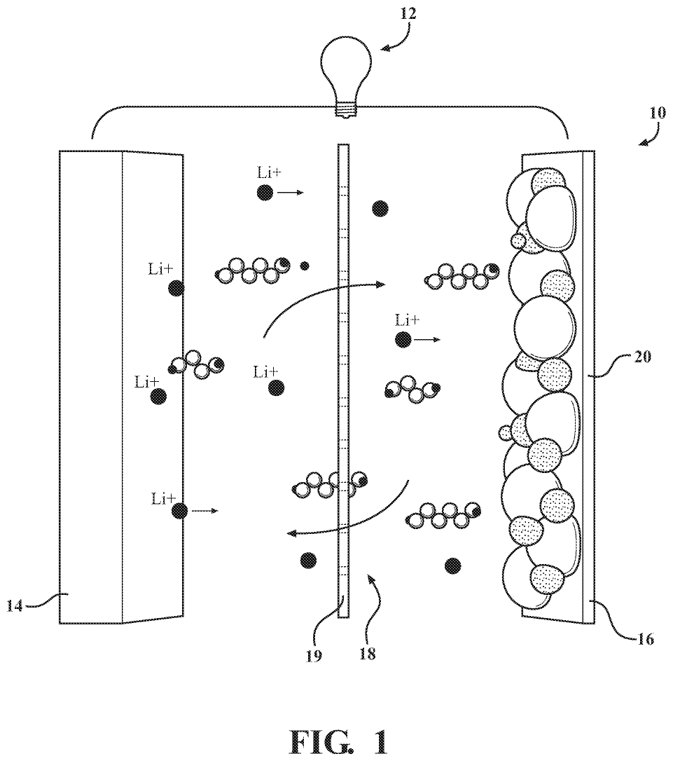

Referring to FIG. 1, an electrical energy storage cell 10 powering a load 12 is depicted. The electrical energy storage cell 10 is specifically shown as a lithium-sulfur (Li—S) battery having a lithium anode 14, a sulfur cathode 16, and an electrolyte 18 surrounding the anode, cathode, and a flowing through a separator 19. The Li—S battery is a type of rechargeable battery notable for its high specific energy. The battery 10 may be used to power such diverse items as toys, consumer electronics, and motor vehicles. The subject vehicle may include, but not be limited to, a commercial vehicle, industrial vehicle, passenger vehicle, aircraft, watercraft, train or the like. It is also contemplated that the vehicle may be a mobile platform, such as an airplane, all-terrain vehicle (ATV), boat, personal movement apparatus, robot and the like to accomplish the purposes of this disclosure.

The low atomic weight of lithium and moderate atomic weight of sulfur means that Li—S batteries are relatively light (having density close to the density of water). Due to the use of sulfur, lithium-sulfur batteries also have higher energy density and reduced cost, as compared with, for example, lithium-ion batteries. Contemporary rechargeable Li-S batteries employ cyclic ethers, short-chain ethers, or glycol ethers, frequently with an additive for lithium surface passivation, as solvent for the electrolyte 18. Sulfur, however, has very low electrical conductivity. Consequently, Li—S batteries generally require a greater mass of the employed conducting agent to exploit the entire contribution of the battery's active mass to the battery's capacity. Mixing sulfur elements with a conductive material, such as carbon, generates an energy dense cathode structure with the requisite conductivity.

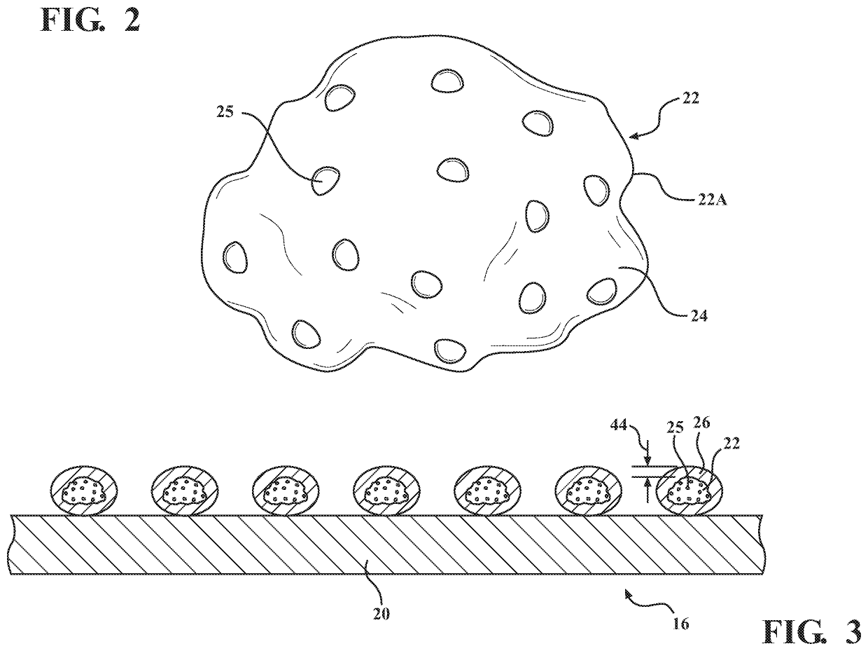

As shown in FIG. 2, the sulfur cathode 16 has a substrate 20 supporting constituent particles 22 having a composite structure. In the Li—S battery, the substrate 20 acts as an electrical current collector and may be constructed from aluminum. The constituent particles 22 form the active material in the sulfur cathode 16 and may be adhered to the substrate 20 via a specially formulated binder. The composite structure of constituent particles 22 uses a porous material matrix 24 to accept and retain sulfur elements 25. Specifically, the composite structure may be carbon-sulfur with a conductive carbon matrix 24 supporting the sulfur elements 25, thus forming a sulfur-infused constituent particle 22. Specifically, wherein the constituent particles 22 are made up of the carbon matrix 24 retaining the sulfur elements 25, each constituent particle may have a size, i.e., dimension across the particle, in a range of 10 nanometers to 500 microns, and more specifically in a range of 5 to 20 microns.

A key issue of Li—S battery 10 is the polysulfide “shuttle” effect that is responsible for the progressive leakage of active material, i.e., sulfur from the cathode 16 resulting in low life cycle of the battery. The electrolyte plays a key role in Li—S batteries, acting both on the shuttle effect by the polysulfide dissolution and the solid electrolyte interface stabilization at anode surface. While sulfate and Li₂S are relatively insoluble in most electrolytes, many intermediate polysulfides are not. The dissolution of Li₂Sₙ into electrolytes generally causes irreversible loss of active sulfur, and a concomitant reduction in battery's energy storage capacity.

To mitigate the dissolution of polysulfide (Li₂Sₙ) into the electrolyte 18 and enhance conductivity of the sulfur cathode 16, the sulfur cathode employs a homogenous, uniform thickness, thin film coating 26, as shown in FIG. 3. The coating 26 is configured to uniformly cover constituent sulfur-infused particles 22 conglomerated on the surface of the substrate 16. The homogenous uniform thickness film coating 26 is applied to an outer surface 22A of the constituent particles 22. For the purposes of the present disclosure, with respect to the sulfur cathode 16, the term “uniform thickness” is herein defined as a thickness having no aggregate localized collection of target material along the surface of the sulfur cathode. The thickness of the homogenous thin film coating 26 may be in a range of 1-500 nanometers, and more specifically in a range of 5-50 nanometers. The coating 26 may be either conductive or semi-conductive. The material of the coating 26 may be a carbon allotrope, such as graphite or grapheme, a metal conductor, for example aluminum, titanium, nickel, chromium, silver, gold, platinum, palladium, or indium, or a semiconductor, such as an oxide or a nitride.

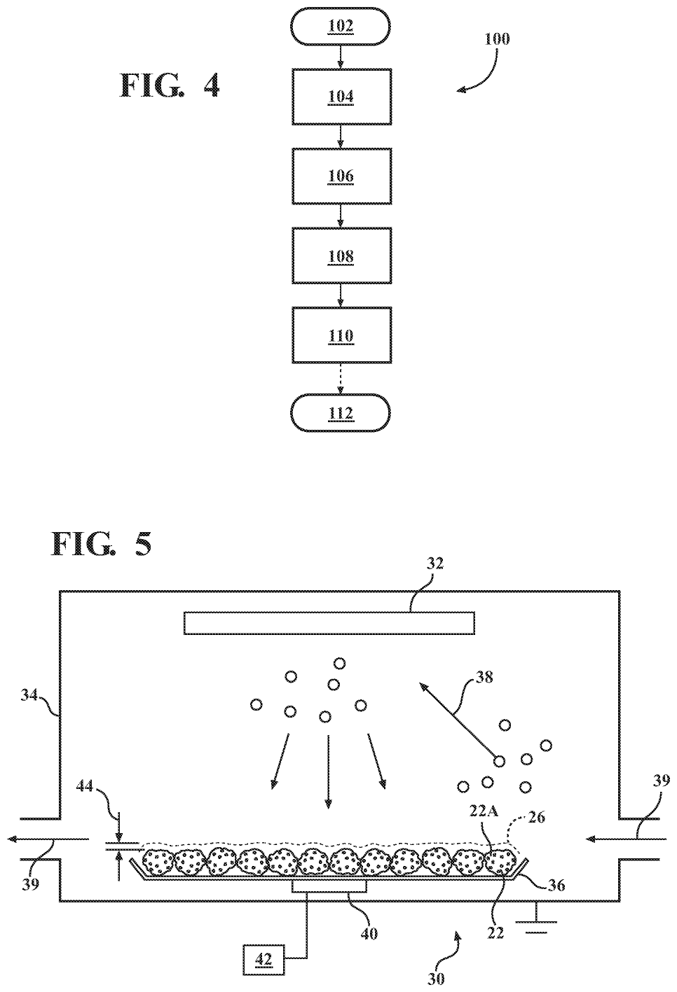

A method 100 of applying the homogenous film coating 26 to a constituent particle 22, such as having the carbon matrix 24 supporting the sulfur elements 25 of the cathode 16 described with respect to FIGS. 1-3, is shown in FIG. 4 and disclosed in detail below. The method 100 may therefore be employed to enhance conductivity of the sulfur cathode 16, and mitigate leakage of polysulfide from the sulfur cathode into the electrolyte 18. The method 100 may be applied to various constituent particles 22, and, more specifically, constituent particles having a matrix composite structure where a porous material matrix supports energy dense particles. However, for exemplary purposes, the method will be described specifically with reference to the constituent particles 22 with the composite structure of carbon matrix 24 supporting sulfur elements 25 of the cathode 16 for the battery 10 shown in FIGS. 1-3. Moreover, the method includes operating a system 30, as shown in FIG. 5, configured to generate the coating 26 on the surface 22A of the particles' 22 composite structure.

Method 100 commences in frame 102 with setting up a target element 32 in a sputtering chamber 34 (shown in FIG. 5), such as a cavity magnetron, which is part of the system 30. The cavity magnetron is generally a high-powered vacuum tube that generates microwaves using an interaction of a stream of electrons with a magnetic field while moving past a series of open metal cavities or cavity resonators, Electrons pass by the openings to these cavities and cause radio waves to oscillate within, similar to the way a whistle produces a tone when excited by an air stream blown past its opening. The frequency of the microwaves i.e., the resonant frequency, is generally determined by the cavity's physical dimensions. The target element 32 may be a carbon allotrope, such as graphite or grapheme, a metal conductor, for example aluminum, titanium, nickel, chromium, silver, gold, platinum, palladium, or indium, or a semiconductor, such as an oxide or a nitride.

Following frame 102, the method advances to frame 104. In frame 104, the method includes setting up and arranging a receptacle 36, such as a tray, in the sputtering chamber 34. The receptacle 36 is part of the system 30 and may be constructed or formed from a suitable high strength material such as steel. After frame 104, the method proceeds to frame 106. In frame 106 the method includes arranging the constituent particle(s) 22 on the receptacle 36. According to the method, the receptacle 36 may be arranged in the sputtering chamber 34 already with the constituent particle(s) 22 thereon, or the constituent particle(s) may be arranged on the receptacle 36 after the receptacle has been arranged in the sputtering chamber. Therefore, frame 106 may be accessed by the method before frame 104.

From frame 106 (or frame 104), the method moves on to frame 108, where the method includes bombarding the target element 32 via energetic particles 38 to eject material from the target element and deposit the material onto the constituent particle(s) 22. Specifically, bombarding the target element via energetic particles 38 may include injecting argon gas 39 or plasma into the sputtering chamber 34. Additionally, in frame 108, the method may also include maintaining a vacuum, such as 1×10⁻³ mBarr and maintaining a temperature in a range of 25 to 115 degrees Celsius in the sputtering chamber 34 during the bombardment of the target element 32.

After frame 108 the method may proceed to frame 110, where the method includes agitating, such as vibrating, the receptacle 36 during the bombarding to apply the material of the target element 32 onto the constituent particle(s) 22, via the coating elements released on atomic level, as the homogenous film coating 26. As the receptacle 36 is being agitated, the constituent particle(s) 22 are shuffled and turned relative to the receptacle, thereby sporadically presenting various parts of the constituent particle(s)′ surface 22A to the material ejected from the target element 32. Accordingly, agitation of the receptacle 36 promotes uniform deposition of the target element 32 material onto the constituent particle(s) 22.

Agitating the fixture 36 may include inducing vibration via predefined strokes at a frequency in a range of 2,000 to 20,000 strokes per minute. In the system 30, such agitating of the receptacle 36 may be accomplished via a suitable agitation device 40, such as a DC electric motor or an ultrasonic transducer. The system 30 may also include an electronic controller 42. The agitation device 40 may be regulated via the electronic controller 42 programmed induce agitation to the receptacle 36 at the selected frequency over a predetermined duration of time t to generate the coating 26 of a substantially uniform target thickness 44 on the surface 22A of the constituent particle(s) 22.

Generally, ultrasonic transducers are used to convert another type of energy into ultrasonic vibration. There are several basic types of ultrasonic transducers, generally classified by the energy source and the medium into which ultrasonic waves are being generated. Mechanical ultrasonic transducers include gas-driven, pneumatic, or liquid-driven transducers, such as hydrodynamic oscillators and vibrating blades. Mechanical transducers are generally limited to low ultrasonic frequencies. Electromechanical transducers either convert an electrical signal into sound waves or convert a sound wave into an electrical signal.

Electromechanical transducers generally include piezoelectric or magnetostrictive devices. A magnetostrictive transducer makes use of a magnetic material in which an applied oscillating magnetic field squeezes together atoms of the material, creating a periodic change in the length of the material and thus producing a high-frequency mechanical vibration. Magnetostrictive transducers are used primarily in the lower frequency ranges. Piezoelectric transducers are readily employed over the entire frequency range and at all output levels. Piezoelectric and magnetostrictive transducers also are employed as ultrasonic receivers, picking up an ultrasonic vibration and converting it into an electrical oscillation.

The electronic controller 42 may include a processor and tangible, non-transitory memory, which includes instructions for operation of the system 30 programmed therein. The memory may be an appropriate recordable medium that participates in providing computer-readable data or process instructions. Such a recordable medium may take many forms, including but not limited to non-volatile media and volatile media. Non-volatile media for the electronic controller 42 may include, for example, optical or magnetic disks and other persistent memory. Volatile media may include, for example, dynamic random access memory (DRAM), which may constitute a main memory. Such instructions may be transmitted by one or more transmission medium, including coaxial cables, copper wire and fiber optics, including the wires that comprise a system bus coupled to a processor of a computer, or via a wireless connection.

Memory of the electronic controller 42 may also include a flexible disk, hard disk, magnetic tape, another magnetic medium, a CD-ROM, DVD, another optical medium, etc. The electronic controller 42 may be configured or equipped with other required computer hardware, such as a high-speed clock, requisite Analog-to-Digital (A/D) and/or Digital-to-Analog (D/A) circuitry, input/output circuitry and devices (I/O), as well as appropriate signal conditioning and/or buffer circuitry. Algorithms required by the electronic controller 42 or accessible thereby may be stored in the memory and automatically executed to provide the required functionality of the system 30.

Additionally, in frame 110, the method may include continuing to maintain the vacuum and the above temperature in the sputtering chamber 34 during agitation of the tooling fixture 36. Multiple successive layers of the target element 32 material may be deposited onto the surface 22A of the constituent particle(s) 22 to generate the substantially uniform target thickness 44 of the homogenous film coating 26. The target thickness 44 may be in the range of 1-500 nanometers, and more specifically in a range of 5-50 nanometers, as discussed above with respect to FIGS. 1-3. The deposition of the material on the constituent particle(s) 22 may be regulated via controlling duration of time the method is run in frames 108-110. The method may conclude in frame 112 with the completion of the cathode 16 having the coating 26 of the uniform target thickness 44 deposited onto the surface 22A of the constituent particle(s) 22.

The detailed description and the drawings or figures are supportive and descriptive of the disclosure, but the scope of the disclosure is defined solely by the claims. While some of the best modes and other embodiments for carrying out the claimed disclosure have been described in detail, various alternative designs and embodiments exist for practicing the disclosure defined in the appended claims. Furthermore, the embodiments shown in the drawings or the characteristics of various embodiments mentioned in the present description are not necessarily to be understood as embodiments independent of each other. Rather, it is possible that each of the characteristics described in one of the examples of an embodiment may be combined with one or a plurality of other desired characteristics from other embodiments, resulting in other embodiments not described in words or by reference to the drawings. Accordingly, such other embodiments fall within the framework of the scope of the appended claims.

What is claimed is:

1. A method of applying a homogenous film coating to a constituent particle of a component, the method comprising:
setting up a target element in a sputtering chamber;
arranging a receptacle in the sputtering chamber;
arranging the constituent particle on the receptacle (tray);
bombarding the target element via energetic particles to eject material from the target element and deposit the material onto the constituent particle; and
agitating the receptacle during the bombarding to apply the material to the constituent particle as the homogenous film coating.

2. The method of claim 1, wherein the material is selected from a list of carbon allotrope and metal conductors, or semiconductors.

3. The method of claim 1, wherein the homogenous film coating has a thickness in a range of 5-50 nanometers.

4. The method of claim 1, wherein agitating the receptacle includes inducing vibration via predefined strokes at a frequency in a range of 2,000 to 20,000 strokes per minute.

5. The method of claim 1, wherein the constituent particle has a matrix composite structure having a porous material matrix supporting energy dense elements.

6. The method of claim 1, wherein size of the constituent particle is in a range of 5 to 20 microns.

7. The method of claim 1, further comprising maintaining a vacuum of 1×10⁻³ mBarr in the sputtering chamber during each of bombarding the target element and agitating the receptacle.

8. The method of claim 1, further comprising maintaining a temperature in a range of 25 to 115 degrees Celsius in the sputtering chamber during each of bombarding the target element and agitating the receptacle.

9. The method of claim 1, wherein agitating the receptacle is accomplished via DC electric motor or an ultrasonic transducer.

10. The method of claim 1, wherein bombarding the target element via energetic particles includes injecting argon gas into the sputtering chamber.

11. A method of applying a homogenous thin film coating to a sulfur-infused constituent particle for a sulfur cathode in a lithium-sulfur battery, the method comprising:
setting up a target element in a sputtering chamber;
arranging a receptacle in the sputtering chamber;
arranging the sulfur-infused constituent particle on the receptacle;
bombarding the target element via energetic particles to eject material from the target element and deposit the material onto the sulfur-infused constituent particle; and
agitating the receptacle during the bombarding to apply the material to the sulfur-infused constituent particle as the homogenous film coating to thereby enhance conductivity of the sulfur-infused constituent particle and mitigate leakage of polysulfide from the sulfur cathode in the lithium-sulfur battery.

12. The method of claim 11, wherein the material is selected from a list of carbon allotrope and metal conductors, or semiconductors.

13. The method of claim 11, wherein the homogenous film coating has a thickness in a range of 5-50 nanometers.

14. The method of claim 11, wherein agitating the receptacle includes inducing vibration via predefined strokes at a frequency in a range of 2,000 to 20,000 strokes per minute.

15. The method of claim 11, wherein the sulfur-infused constituent particle has a carbon-sulfur composite structure having a carbon matrix supporting sulfur elements.

16. The method of claim 11, wherein size of the sulfur-infused constituent particle is in a range of 5 to 20 microns.

17. The method of claim 11, further comprising maintaining a vacuum of 1×10⁻³ mBarr in the sputtering chamber during each of bombarding the target element and agitating the receptacle.

18. The method of claim 11, further comprising maintaining a temperature in a range of 25 to 115 degrees Celsius in the sputtering chamber during each of bombarding the target element and agitating the receptacle.

19. The method of claim 11, wherein agitating the receptacle is accomplished via DC electric motor or an ultrasonic transducer.

20. The method of claim 11, wherein bombarding the target element via energetic particles includes injecting argon gas into the sputtering chamber.
